(19) United States
(12) Patent Application Publication
(10) Pub. No.: US 2025/0107004 A1
(43) Pub. Date: Mar. 27, 2025

(54) WIRING BOARD AND MOUNTING STRUCTURE USING THE SAME

(71) Applicant: KYOCERA Corporation, Kyoto-shi (JP)

(72) Inventor: Rintaro KAMIMURA, Satsumasendai-shi (JP)

(73) Assignee: KYOCERA Corporation, Kyoto-shi (JP)

(21) Appl. No.: 18/895,148

(22) Filed: Sep. 24, 2024

(30) Foreign Application Priority Data
Sep. 26, 2023 (JP) 2023-163542

(51) Int. Cl. H05K 1/18; H05K 1/11

(52) U.S. Cl. CPC H05K 1/181; H05K 1/111; H05K 2201/1003

(57) ABSTRACT

A wiring board according to the present disclosure, includes: a build-up layer including; a first insulation layer having a first surface and a second surface located opposite to the first surface; and a first electrical conductor layer located on the first surface; and a solder resist covering a portion of, the first surface and the first electrical conductor layer. The build-up layer includes a mounting region on the first surface in which an electronic component including an inductor is mounted. The mounting region includes a first region at a location opposite to the inductor when the electronic component is mounted. The first electrical conductor layer and the solder resist are not located in the first region.

### BACKGROUND OF THE INVENTION

### 1. Technical Field

The present invention relates to a wiring board and a mounting structure using the same.

### 2. Background

An example of a semiconductor element mounted on a wiring board is a semiconductor element including an inductor as disclosed in JP 4878502 B. In a wiring board for mounting a semiconductor element including an inductor, an electrical conductor is disposed in such a manner as to not be in a region opposite to the inductor included in the semiconductor element. This is because once the electrical conductor has been positioned, eddy current and electrostatic capacitance are generated, reducing the effect of the inductor.

### SUMMARY

A wiring board according to the present disclosure, includes: a build-up layer including; a first insulation layer having a first surface and a second surface located opposite to the first surface; and a first electrical conductor layer located on the first surface; and a solder resist covering a portion of, the first surface and the first electrical conductor layer. The build-up layer includes a mounting region on the first surface in which an electronic component including an inductor is to be mounted. The mounting region includes a first region at a location opposite to the inductor when the electronic component is mounted. The first electrical conductor layer and the solder resist are not located in the first region.

A mounting structure according to the present disclosure, includes: the wiring board; and an electronic component located on the mounting region of the wiring board. The electronic component includes an inductor facing the first region through an air gap between the inductor and the wiring board.

### BRIEF DESCRIPTION OF THE DRAWINGS

FIG. 1 is an explanatory diagram for illustrating a mounting structure in which an electronic component is mounted on a wiring board according to a first embodiment of the present disclosure.

FIG. 2 is an explanatory diagram for illustrating a mounting structure in which an electronic component is mounted on a wiring board according to a second embodiment of the present disclosure.

FIG. 3 is an explanatory diagram for illustrating a mounting structure in which an electronic component is mounted on a wiring board according to a third embodiment of the present disclosure.

FIG. 4 is an explanatory diagram for illustrating a mounting structure in which an electronic component is mounted on a wiring board according to a fourth embodiment of the present disclosure.

FIG. 5 is an explanatory diagram for illustrating a mounting structure in which an electronic component is mounted on a wiring board according to a fifth embodiment of the present disclosure.

### DETAILED DESCRIPTION

In a wiring board on which a semiconductor element including an inductor is mounted, even if an attempt is made not to dispose an electrical conductor in a region facing the inductor included in the semiconductor element, the effect of reducing the adverse effect due to electrostatic capacitance may be small, and the effect of the inductor may not be sufficiently exerted. Thus, there is a demand for a wiring board that can efficiently exert the effect of the inductor included in the mounted semiconductor element.

A wiring board according to the present disclosure can efficiently exert the effect of the inductor included in the mounted semiconductor element by having the configuration described in the section “SUMMARY” above.

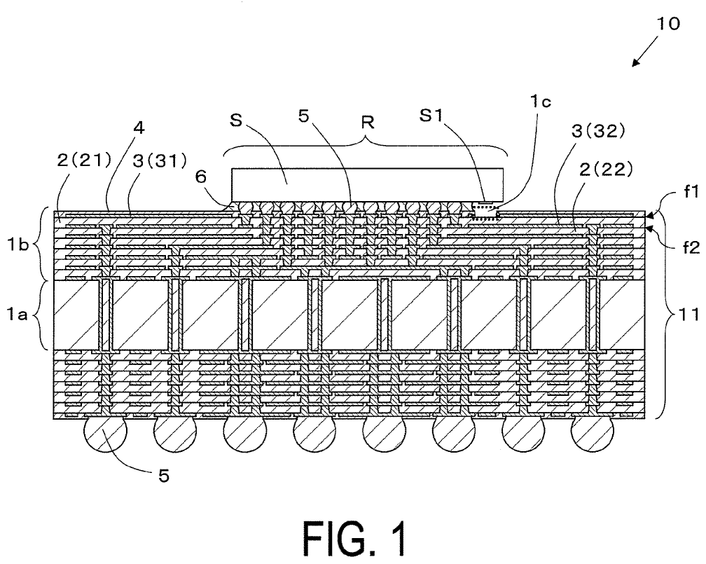

In a first embodiment of the present disclosure, a wiring board will be described with reference to FIG. 1. FIG. 1 is an explanatory diagram for illustrating a mounting structure 10 in which an electronic component S is mounted on a wiring board 11 according to a first embodiment of the present disclosure. A wiring board 11 according to an embodiment includes a core layer 1a and a build-up layer 1b.

In the wiring board 11 illustrated in FIG. 1, the core layer 1a is located at a substantially central portion in the thickness direction of the wiring board 11. The core layer 1a is not particularly limited as long as it has insulation. Examples of a material with insulation include resins such as epoxy resin, bismaleimide-triazine resin, polyimide resin and polyphenylene ether resin. Only one of these resins may be used, or two or more of these resins may be mixed. The thickness of the core layer 1a is not particularly limited. The core layer 1a may have a thickness of, for example, 100 μm or more and 1500 μm or less.

The core layer 1a may include a reinforcing material. Examples of the reinforcing material include insulation fabric materials such as glass fibers, glass nonwoven fabrics, aramid nonwoven fabrics, aramid fibers, and polyester fibers. Only one type of reinforcing material may be used, or two or more types may be used in combination. Furthermore, inorganic insulation fillers such as silica, barium sulfate, talc, clay, glass, calcium carbonate, and titanium oxide may be dispersed in the core layer 1a. Only one type of inorganic insulation filler may be used, or two or more types may be used in combination.

Through-hole conductors are disposed in the core layer 1a and electrically connect the upper and lower surfaces of the core layer 1a to each other. The through-hole conductors are located in the through holes penetrating the upper and lower surfaces of the core layer 1a. The through-hole conductors are composed of, for example, a metal such as copper, specifically, metal plating such as copper plating. The through-hole conductors may be formed only on the inner wall surface or may fill the through holes.

Electrical conductor layers 3 are located on the upper and lower surfaces of the core layer 1a. The electrical conductor layers 3 are not limited as long as each is an electrical conductor such as a metal. Specifically, the electrical conductor layers 3 are formed of a metal foil such as a copper foil, or a metal plating such as a copper plating. The thickness of the electrical conductor layers 3 is not particularly limited. The electrical conductor layers 3 may each have a thickness of, for example, 5 μm or more and 25 μm or less. At least some of the electrical conductor layers 3 located on the upper and lower surfaces of the core layer 1a are connected to the through-hole conductors. Thus, the upper and lower surfaces of the core layer 1a are electrically connected to each other.

The build-up layer 1b is located on each of the upper and lower surfaces of the core layer 1a. The build-up layer 1b has a structure in which insulation layers 2 and the electrical conductor layers 3 are layered. Same as the core layer 1a, the insulation layers 2 are not particularly limited as long as each has insulation. Examples of a material with insulation include resins such as epoxy resin, bismaleimide-triazine resin, polyimide resin, and polyphenylene ether resin. Only one of these resins may be used, or two or more of these resins may be mixed.

The insulation layers 2 may be of the same resin or of different resins. The insulation layers 2 and the core layer 1a may be of the same resin or of different resins. The thickness of the insulation layers 2 is not particularly limited. The insulation layers 2 may each have a thickness of, for example, 10 μm or more and 50 μm or less. The insulation layers 2 may have the same thickness or different thicknesses.

The insulation layers 2 may include a reinforcing material. Examples of the reinforcing material include insulation fabric materials such as glass fibers, glass nonwoven fabrics, aramid nonwoven fabrics, aramid fibers, and polyester fibers. Only one type of reinforcing material may be used, or two or more types may be used in combination. Furthermore, inorganic insulation fillers such as silica, barium sulfate, talc, clay, glass, calcium carbonate, and titanium oxide may be dispersed in the insulation layers 2. Only one type of inorganic insulation filler may be used, or two or more types may be used in combination.

Via-hole conductors are disposed in the insulation layer 2 for electrically connecting the upper and lower surfaces of the insulation layer 2. The via-hole conductors are located in via holes penetrating the upper and lower surfaces of the insulation layer 2. The via-hole conductors are formed of, for example, a metal plating such as a copper plating. The via-hole conductors are connected to the electrical conductor layers 3 located on both surfaces of the insulation layer 2. The via-hole conductors may fill the via holes or may be disposed only on the inner surface of the via hole.

The electrical conductor layer 3 is located on a first surface f1 of the insulation layer 2. In the present specification, “first surface f1 of the insulation layer 2” means a surface farther from the core layer 1a among both surfaces of the insulation layer 2. “Second surface f2 of the insulation layer 2” means a surface opposite to the first surface f1, that is, a surface closer to the core layer 1a. As described above, the electrical conductor layer 3 is not limited as long as it is an electrical conductor such as a metal.

As illustrated in FIG. 1, a solder resist 4 is located on the surface of the build-up layer 1b. The solder resist 4 is formed of a resin, such as an acrylic modified epoxy resin. The solder resist 4 is provided with a plurality of openings in order to electrically connect the electrical conductor layer 3 to an electrode of the electronic component S described below via a solder 5. That is, the electrical conductor layer 3 exposed to the opening of the solder resist 4 functions as a plurality of electrodes of the wiring board 11.

Among the electrical conductor layers 3 included in the build-up layer 1b, a first electrical conductor layer 31 located on the outermost layer of the build-up layer 1b is partially covered with the solder resist 4. Among the insulation layers 2 included in the build-up layer 1b, the first electrical conductor layer 31 is located on the first surface f1 of a first insulation layer 21 located on the outermost layer of the build-up layer 1b.

The build-up layer 1b has a mounting region R on the first surface f1 of the first insulation layer 21. The mounting region R is defined as a region including a plurality of electrodes of the wiring board 11, for example. The electronic component S including an inductor S1 is mounted in the mounting region R. As illustrated in FIG. 1, the mounting region R includes a first region 1c at a location opposite to the inductor S1 when the electronic component S is mounted. The surface area of the first region 1c may be the same size as the surface area overlapping the inductor S1 in plane perspective, for example, or may be larger than the surface area of the inductor S1 such that the periphery of the inductor S1 falls within the periphery of the first region 1c. The inductor S1 has a function of converting electrical energy into magnetic energy and storing it, for example.

As illustrated in FIG. 1, the first electrical conductor layer 31 and the solder resist 4 are not located in the first region 1c of the wiring board 11. Since both the first electrical conductor layer 31 and the solder resist 4 are not located in the first region 1c, the effect of reducing the adverse effect due to the electrostatic capacitance is increased. As a result, the effect of the inductor S1 included in the mounted electronic component S is efficiently exerted.

The method of forming the first region 1c is not limited as long as both the first electrical conductor layer 31 and the solder resist 4 can be made absent. The method includes a method in which the first electrical conductor layer 31 and the solder resist 4 are not provided in the portion corresponding to the first region 1c when the first electrical conductor layer 31 and the solder resist 4 are formed, or a method in which the first electrical conductor layer 31 and the solder resist 4 in the portion corresponding to the first region 1c are removed by laser processing or drilling processing.

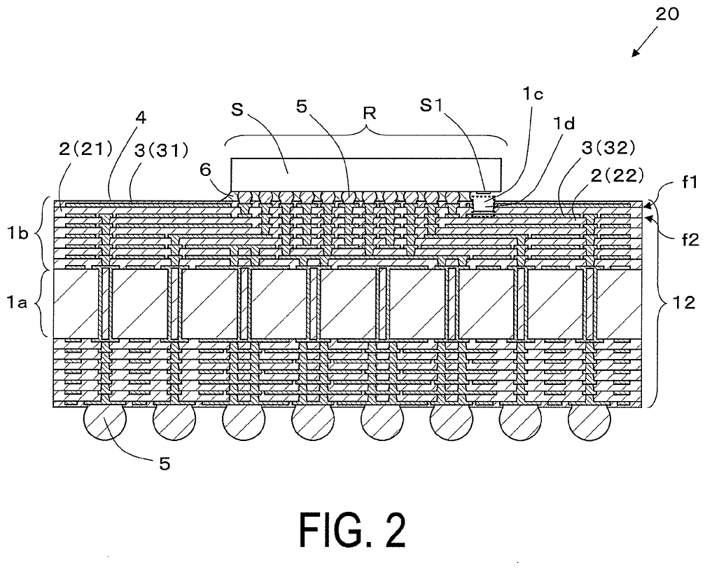

Next, in a second embodiment of the present disclosure, the wiring board will be described with reference to FIG. 2. FIG. 2 is an explanatory diagram for illustrating a mounting structure 20 in which the electronic component S is mounted on a wiring board 12 according to a second embodiment of the present disclosure. In the wiring board 12, the same members as those of the wiring board 11 are denoted by the same reference numerals, and a detailed description thereof will be as described above and omitted.

The first electrical conductor layer 31 and the solder resist 4 are not located in the first region 1c of the wiring board 11, while in the wiring board 12, the first region 1c further includes a recessed portion 1d opening in the first region 1c in the first insulation layer 21. Specifically, a part further recessed from the first surface f1 of the first insulation layer 21 to the core layer 1a side at the bottom portion of the first region 1c, corresponds to the recessed portion 1d. That is, the first electrical conductor layer 31 and the solder resist 4 are not located in the first region 1c of the wiring board 12, and the recessed portion 1d opening in the first region 1c is located recessed from the first surface f1 of the first insulation layer 21 to the core layer 1a side.

In plane perspective, the surface area of the opening of the recessed portion 1d may be the same size as the surface area overlapping the inductor S1 and may be larger than the surface area of the inductor S1 such that the periphery of the inductor S1 is located within the periphery of the opening. When the surface area of the opening is larger than the surface area of the inductor S1 in plane perspective, even if a shift occurs when the electronic component S is mounted on the wiring board 12, it is advantageous that the inductor S1 easily tends to face the opening.

Since the first region 1c further includes the recessed portion 1d, a wider air gap (air layer) is provided between the inductor S1 and the wiring board 12 (the bottom portion of the recessed portion 1d). Thus, adverse effects due to the electrostatic capacitance formed between the inductor S1 and the electrical conductor layer 3 located on the core layer 1a side are also reduced. As a result, the effect of the inductor S1 included in the mounted electronic component S is more efficiently exerted. The method of forming the recessed portion 1d is not limited, and may be formed by, for example, laser processing or drilling processing. In the wiring board 12 according to the embodiment illustrated in FIG. 2, the bottom portion of the recessed portion 1d is located in the first insulation layer 21. That is, the recessed portion 1d does not penetrate the first insulation layer 21.

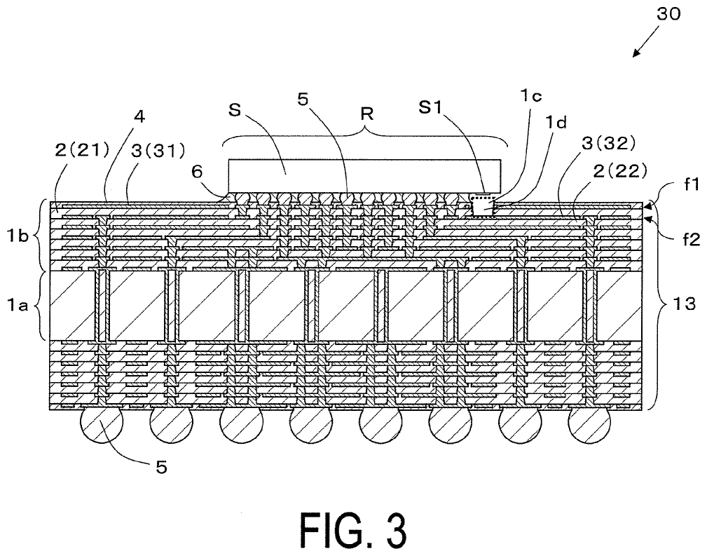

Next, in a third embodiment of the present disclosure, the wiring board will be described with reference to FIG. 3. FIG. 3 is an explanatory diagram for illustrating a mounting structure 30 in which the electronic component S is mounted on a wiring board 13 according to a third embodiment of the present disclosure. In the wiring board 13, the same members as those of the wiring board 11 are denoted by the same reference numerals, and detailed description thereof is as described above and omitted.

As illustrated in FIG. 3, in the wiring board 13, the build-up layer 1b includes a second insulation layer 22 in contact with the second surface f2 of the first insulation layer 21, and a second electrical conductor layer 32 located between the first insulation layer 21 and the second insulation layer 22. The wiring board 13 includes the recessed portion 1d in the first insulation layer 21, which opens in the first region 1c, and the bottom portion of the recessed portion 1d is in the second electrical conductor layer 32. Thus, a wide air gap (air layer) is provided between the inductor S1 and the wiring board 13 (the bottom portion of the recessed portion 1d).

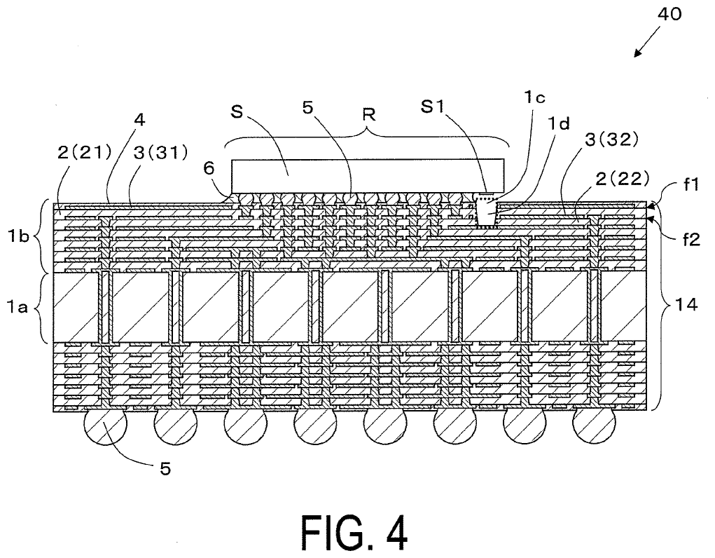

Further, as illustrated in FIG. 4, in a wiring board 14 according to the fourth embodiment of the present disclosure, the bottom portion of the recessed portion 1d penetrates the second electrical conductor layer 32 and is located in the electrical conductor layer 3 on the side of the core layer 1a. FIG. 4 is an explanatory diagram illustrating a mounting structure 40 in which the electronic component S is mounted on the wiring board 14 according to a fourth embodiment of the present disclosure. In the wiring board 14, the same members as those of the wiring board 11 are denoted by the same reference numerals, and a detailed description thereof will be as described above and omitted.

As illustrated in FIG. 4, the recessed portion 1d may penetrate the second electrical conductor layer 32 and be more deeply recessed. The recessed portion 1d illustrated in FIG. 4 is located in the electrical conductor layer 3 by one layer closer to the core layer 1a than the second electrical conductor layer 32. However, the bottom portion of the recessed portion 1d may be located further closer to the core layer 1a than the recessed portion 1d illustrated in FIG. 4 and may be located in an insulation layer just below the second insulation layer 22. As described above, the depth of the recessed portion 1d is not limited. The depth of the recessed portion 1d may be appropriately adjusted in such a manner that the effect of the inductor S1 can easily be applied.

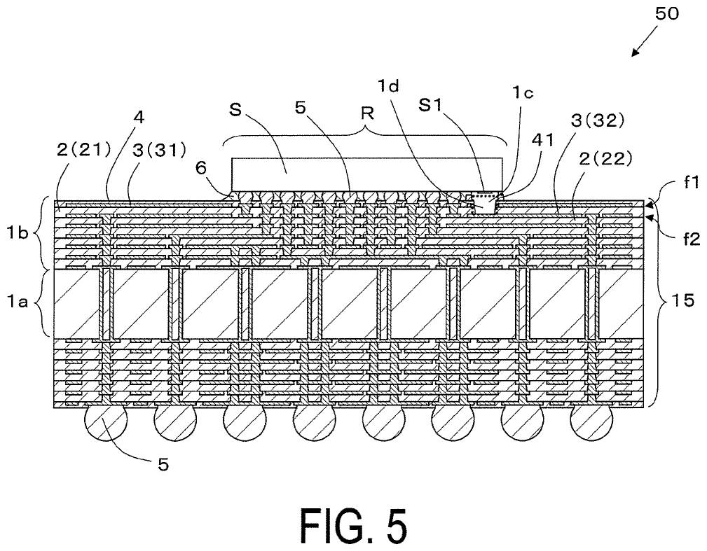

Next, in a fifth embodiment of the present disclosure, the wiring board will be described with reference to FIG. 5. FIG. 5 is an explanatory diagram illustrating a mounting structure 50 in which an electronic component S is mounted on a wiring board 15 according to a fifth embodiment of the present disclosure. In a wiring board 15, the same members as those of the wiring board 11 are denoted by the same reference numerals, and a detailed description thereof will be as described above and omitted.

In the wiring board 15, the solder resist 4 includes a wall 41 projecting in a direction opposite to the first surface f1 and surrounding the first region 1c. That is, the wall 41 projects from the first surface f1 side to the electronic component S side to be mounted. The wall 41 such as that described above is not located in the wiring board 11 according to the first embodiment, the wiring board 12 according to the second embodiment, the wiring board 13 according to the third embodiment, and the wiring board 14 according to the fourth embodiment. The disposition of the wall 41 makes it difficult for an underfill 6 to flow into the first region 1c when the underfill 6 described below fills a region between the electronic component S and the mounting region R.

When the underfill 6 flows into the first region 1c, the air gap (air layer) between the inductor S1 and the wiring board 15 is narrowed by the underfill 6. As a result, the effect of reducing the adverse effect of electrostatic capacitance is less effective. As described above, the disposition of the wall 41 makes it difficult for the underfill 6 to flow into the first region 1c, and the effect of reducing the adverse effect of electrostatic capacitance is sufficiently effective.

The height of the wall 41 is not limited. In order to substantially prevent the underfill 6 from flowing into the first region 1c, the wall 41 may have a height that reaches the electronic component S to be mounted. When the wall 41 has a height of 50% or more of the length from the solder resist 4 to the electronic component S, the inflow of the underfill 6 is sufficiently reduced. When the angle formed by the wall 41 and the first surface f1 is 45° or more and 90° or less, it is advantageous in that the underfill 6 is less likely to flow into the first region 1c. For example, when the angle is 60° or more, the inflow reduction effect is further improved.

The wiring board 15 is the wiring board 13 provided with the wall 41. The wiring board 15 is merely an example of an embodiment in which the solder resist 4 includes the wall 41. The solder resist 4 may also include the wall 41 in the wiring board 11 according to the first embodiment, the wiring board 12 according to the second embodiment, and the wiring board 14 according to the fourth embodiment, described above. Of course, the solder resist may include a wall in any wiring board within the scope of the present disclosure.

Next, a mounting structure according to the present disclosure will be described with reference to FIG. 1. As illustrated in FIG. 1, the mounting structure 10 according to an embodiment includes the wiring board 11 according to an embodiment and the electronic component S. The electronic component S is mounted in the mounting region R located on the surface of the build-up layer 1b (on the first surface of the first insulation layer 21). In the mounting region R, the electrodes of the electronic component S are connected via the solder 5 to the electrical conductor layer 3 exposed in the opening of the solder resist 4 located on the surface of the build-up layer 1b.

The electronic component S includes the inductor S1. Examples of the electronic component S having the inductor S1 include an inductor built-in semiconductor element used in various electronic devices. In the mounting structure 10, the inductor S1 faces the first region 1c with a gap (air layer) between the inductor S1 and the wiring board 11 as illustrated in FIG. 1. In this way, the inductor S1 and the first region 1c face each other through a gap, thereby increasing the effect of reducing the adverse effect due to the electrostatic capacitance. As a result, the effect of the inductor S1 included in the mounted electronic component S is efficiently exerted.

As illustrated in FIG. 1, the underfill 6 may be located between the electronic component S and the wiring board 11 (mounting region R). By disposing the underfill 6 between the electronic component S and the wiring board 11, the electronic component S and the wiring board 11 are firmly connected. Examples of the underfill 6 include resins such as epoxy resin.

As illustrated in FIG. 1, in an embodiment, the mounting structure 10 may include the electronic component S located on one surface, and, for example, a motherboard or the like located on the other surface. The mounting structure 10 may also include the electronic components S located on both surfaces of the wiring board 11.

The mounting structures 20, 30, 40, and 50 illustrated in FIGS. 2 to 5 include: the wiring board 12 according to the second embodiment; the wiring board 13 according to the third embodiment; the wiring board 14 according to the fourth embodiment; and the wiring board 15 according to the fifth embodiment, respectively, all of which include the electronic component S.

The embodiments of the present disclosure have been described above. However, the invention according to the present disclosure is not limited to the above-described embodiments, and various modifications and improvements are possible within the scope of the present disclosure illustrated in (1) to (6) below.

(1) A wiring board according to the present disclosure, includes:
a build-up layer including;
a first insulation layer having a first surface and a second surface located opposite to the first surface; and
a first electrical conductor layer located on the first surface;
and a solder resist covering a portion of, the first surface and the first electrical conductor layer. The build-up layer includes a mounting region on the first surface in which an electronic component including an inductor is to be mounted. The mounting region includes a first region at a location opposite to the inductor when the electronic component is mounted. The first electrical conductor layer and the solder resist are not located in the first region.

With respect to the embodiment of the present disclosure, the embodiments illustrated in (2) to (5) below are further disclosed.

(2) In the wiring board according to above (1), the build-up layer includes a recessed portion opening in the first region.

(3) In the wiring board according to (2) above, a bottom portion of the recessed portion is located in the first insulation layer.

(4) In the wiring board according to (2) or (3) above, the build-up layer further includes:
a second insulation layer in contact with the second surface; and
a second electrical conductor layer located between the first insulation layer and the second insulation layer, and
the bottom portion of the recessed portion is in the second electrical conductor layer.

(5) In the wiring board according to any one of (1) to (4) above, the solder resist includes a wall projecting in a direction opposite to the first surface and surrounding the first region.

(6) A mounting structure according to the present disclosure, includes:
a wiring board according to any one of (1) to (5) above; and
an electronic component located on the mounting region of the wiring board. The electronic component includes an inductor facing the first region through an air gap between the inductor and the wiring board.

(7) In the mounting structure according to (6) above,
an underfill is located between the electronic component and the wiring board.

### DESCRIPTION OF THE REFERENCE NUMERALS

11, 12, 13, 14, 15 Wiring board
1a Core layer
1b Build-up layer
1c First region
1d Recessed portion
2 Insulation layer
21 First insulation layer
22 Second insulation layer
3 Electrical conductor layer
31 First electrical conductor layer
32 Second electrical conductor layer
4 Solder resist
41 Wall
5 Solder
6 Underfill
10, 20, 30, 40, 50 Mounting structure
f1 First surface
f2 Second surface
R Mounting region

What is claimed is:

1. A wiring board, comprising:
a build-up layer comprising;
a first insulation layer having a first surface and a second surface located opposite to the first surface; and
a first electrical conductor layer located on the first surface; and
a solder resist covering a portion of, the first surface and the first electrical conductor layer, wherein
the build-up layer comprises a mounting region on the first surface in which an electronic component comprising an inductor is to be mounted,
the mounting region comprises a first region at a location opposite to the inductor when the electronic component is mounted, and
the first electrical conductor layer and the solder resist are not located in the first region.

2. The wiring board according to claim 1, wherein
the build-up layer comprises a recessed portion opening in the first region.

3. The wiring board according to claim 2, wherein
a bottom portion of the recessed portion is located in the first insulation layer.

4. The wiring board according to claim 2, wherein
the build-up layer further comprises a second insulation layer in contact with the second surface; and
a second electrical conductor layer located between the first insulation layer and the second insulation layer, and
the bottom portion of the recessed portion is in the second electrical conductor layer.

5. The wiring board according to claim 1, wherein
the solder resist comprises a wall projecting in a direction opposite to the first surface and surrounding the first region.

6. The wiring board according to claim 2, wherein
the solder resist comprises a wall projecting in a direction opposite to the first surface and surrounding the first region.

7. The wiring board according to claim 3, wherein
the solder resist comprises a wall projecting in a direction opposite to the first surface and surrounding the first region.

8. The wiring board according to claim 4, wherein
the solder resist comprises a wall projecting in a direction opposite to the first surface and surrounding the first region.

9. A mounting structure, comprising:
a wiring board according to claim 1; and
an electronic component located on the mounting region of the wiring board,
the electronic component comprising an inductor facing the first region through an air gap between the inductor and the wiring board.

10. The mounting structure according to claim 9, wherein
an underfill is located between the electronic component and the wiring board.

11. A mounting structure, comprising:
a wiring board according to claim 2; and
an electronic component located on the mounting region of the wiring board,
the electronic component comprising an inductor facing the first region through an air gap between the inductor and the wiring board.

12. The mounting structure according to claim 11, wherein
an underfill is located between the electronic component and the wiring board.

13. A mounting structure, comprising:
a wiring board according to claim 3; and
an electronic component located on the mounting region of the wiring board, the electronic component comprising an inductor facing the first region through an air gap between the inductor and the wiring board.

14. The mounting structure according to claim 13, wherein
an underfill is located between the electronic component and the wiring board.

15. A mounting structure, comprising:
a wiring board according to claim 4; and
an electronic component located on the mounting region of the wiring board,
the electronic component comprising an inductor facing the first region through an air gap between the inductor and the wiring board.

16. The mounting structure according to claim 15, wherein
an underfill is located between the electronic component and the wiring board.

17. A mounting structure, comprising:
a wiring board according to claim 5; and
an electronic component located on the mounting region of the wiring board,
the electronic component comprising an inductor facing the first region through an air gap between the inductor and the wiring board.

18. The mounting structure according to claim 17, wherein
an underfill is located between the electronic component and the wiring board.
